(19) United States
(12) Patent Application Publication
(10) Pub. No.: US 2024/0405060 A1
(43) Pub. Date: Dec. 5, 2024

(54) DISPLAY SUBSTRATES, MASK ASSEMBLIES AND DISPLAY PANELS

(71) Applicants: Chengdu BOE Optoelectronics Technology Co., Ltd., Chengdu, Sichuan (CN); BOE Technology Group Co., Ltd., Beijing (CN)

(72) Inventors: Xinxing GUAN, Beijing (CN); Na BI, Beijing (CN); Jianing LIU, Beijing (CN); Cheng HAN, Beijing (CN); Shun WANG, Beijing (CN); Shuang ZHENG, Beijing (CN); Qihao ZENG, Beijing (CN); Hao LIU, Beijing (CN)

(21) Appl. No.: 18/696,976

(22) PCT Filed: Jun. 9, 2023
(86) PCT No.: PCT/CN2023/099401

§ 371 Date: Mar. 28, 2024

(30) Foreign Application Priority Data
Jun. 24, 2022 (CN) 202210730070.7

(51) Int. Cl. H01L 27/15

(52) U.S. Cl. CPC H01L 27/156

(57) ABSTRACT

A display substrate, a mask assembly and a display panel are provided. The display substrate includes: pixel units arranged in an array and including first pixel units and second pixel units, where, in a row direction, the first pixel units and the second pixel units are alternately arranged; in a column direction, the first pixel units and the second pixel units are alternately arranged; the first pixel unit includes a first sub-pixel, two second sub-pixels, and a third sub-pixel in a virtual quadrilateral; the second pixel unit includes a first sub-pixel, two second sub-pixels, and a third sub-pixel in a virtual hexagon; where adjacent first pixel unit and second pixel unit in the column direction share a first sub-pixel or a third sub-pixel, and adjacent first pixel unit and second pixel unit in the row direction share a second sub-pixel.

### TECHNICAL FIELD

The present disclosure relates to the field of display technologies, and in particular, to a display substrate, a mask assembly and a display panel.

### BACKGROUND

With the development of economy, display panels have been more and more widely used in people's lives. The display panels mainly include a light emitting unit. The light emitting unit includes two electrodes disposed opposite to each other and a light emitting layer between the two electrodes. The two electrodes are electrically connected with a power source to supply power to the light emitting layer. However, existing display panels have a lower resolution.

### SUMMARY

An object of the present disclosure is to provide a display substrate, a mask assembly and a display panel, which can achieve a high-resolution display effect.

According to an aspect of the present disclosure, there is provided a display substrate, including:
pixel units arranged in an array and including first pixel units and second pixel units, where, in a row direction, the first pixel units and the second pixel units are alternately arranged: in a column direction, the first pixel units and the second pixel units are alternately arranged: the first pixel unit includes a first sub-pixel, two second sub-pixels, and a third sub-pixel in a virtual quadrilateral: the second pixel unit includes a first sub-pixel, two second sub-pixels, and a third sub-pixel in a virtual hexagon;
where adjacent first pixel unit and second pixel unit in the column direction share a first sub-pixel or a third sub-pixel, and adjacent first pixel unit and second pixel unit in the row direction share a second sub-pixel.

Further, the virtual hexagon includes two first sides disposed opposite to each other, and the first sides are respectively perpendicular to the column direction: the first sub-pixel and the third sub-pixel in the virtual hexagon are respectively disposed to be attached to the two first sides, and the two second sub-pixels in the virtual hexagon are respectively disposed at two angles formed by another four sides of the virtual hexagon.

Further, the first sub-pixel and the third sub-pixel in the virtual quadrilateral are respectively disposed at two opposite angles of the virtual quadrilateral, and the two second sub-pixels in the virtual quadrilateral are respectively disposed at another two angles of the virtual quadrilateral.

Further, the two second sub-pixels in the virtual hexagon are symmetrically distributed; and/or, the two second sub-pixels in the virtual quadrilateral are symmetrically distributed.

Further, the first sub-pixel is presented as an axisymmetric pattern, and a symmetry axis of the symmetrically distributed two second sub-pixels coincides with a symmetry axis of the first sub-pixel.

Further, the third sub-pixel is presented as an axisymmetric pattern, and the symmetry axis of the symmetrically distributed two second sub-pixels coincides with a symmetry axis of the third sub-pixel.

Further, in the row direction, the first sub-pixel and the third sub-pixel are alternately arranged, and geometric centers of the alternately arranged first sub-pixel and third sub-pixel are on a same straight line; and/or

in the column direction, the first sub-pixel and the third sub-pixel are alternately arranged, and geometric centers of the alternately arranged first sub-pixel and third sub-pixel are on a same straight line.

Further, the first sub-pixel and the third sub-pixel are respectively presented as pentagonal, and the second sub-pixel is presented as quadrilateral.

Further, in the virtual hexagon, a distance between the second sub-pixel and the first sub-pixel is equal to a distance between the second sub-pixel and the third sub-pixel, and the distance between the second sub-pixel and the first sub-pixel is smaller than a distance between the first sub-pixel and the third sub-pixel.

Further, in the virtual quadrilateral, a distance between the second sub-pixel and the first sub-pixel is equal to a distance between the second sub-pixel and the third sub-pixel, and the distance between the second sub-pixel and the first sub-pixel is equal to a distance between the first sub-pixel and the third sub-pixel.

Further, the first sub-pixel and the second sub-pixel are alternately arranged in a first direction, and sides of any adjacent first sub-pixel and second sub-pixel in the first direction are aligned, where the first direction is different from the column direction and the row direction.

Further, a light emitting color of the first sub-pixel, a light emitting color of the second sub-pixel, and a light emitting color of the third sub-pixel are different from each other.

Further, the first sub-pixel is configured to emit red light, the second sub-pixel is configured to emit green light, and the third sub-pixel is configured to emit blue light.

According to an aspect of the present disclosure, there is provided a mask assembly for manufacturing the display substrate. The mask assembly includes:
a first mask plate including a first substrate and a first opening provided in the first substrate, where the first opening corresponds to a first sub-pixel;
a second mask plate including a second substrate and a second opening provided in the second substrate, where the second opening corresponds to a second sub-pixel;
a third mask plate including a third substrate and a third opening provided in the third substrate, where the third opening corresponds to a third sub-pixel.

According to an aspect of the present disclosure, there is provided a display panel, including the display substrate.

In the display substrate, the mask assembly and the display panel according to the present disclosure, adjacent first pixel unit and second pixel unit in the column direction share a first sub-pixel or a third sub-pixel, and adjacent first pixel unit and second pixel unit in the row direction share a second sub-pixel, so that a high-resolution display effect is achieved through a color-borrowing principle.

### BRIEF DESCRIPTION OF DRAWINGS

FIG. 1 is a schematic diagram of a display substrate according to an embodiment of the present disclosure.

FIG. 2 is a partial schematic diagram of a display substrate according to an embodiment of the present disclosure.

FIG. 3 is a schematic diagram of a first mask plate according to an embodiment of the present disclosure.

FIG. 4 is a schematic diagram of a second mask plate according to an embodiment of the present disclosure.

FIG. 5 is a schematic diagram of a third mask plate according to an embodiment of the present disclosure.

Description of reference signs: 1. first pixel unit; 101. first sub-pixel; 102. second sub-pixel; 103. third sub-pixel; 2. second pixel unit; 3. first substrate; 301. first opening; 4. second substrate; 401. second opening; 5. third substrate; 501. third opening.

### DETAILED DESCRIPTION

Examples will be described in detail herein, with the illustrations thereof represented in the drawings. When the following descriptions involve the drawings, like numerals in different drawings refer to like or similar elements unless otherwise indicated. The embodiments described in the following examples do not represent all embodiments consistent with the present disclosure. Rather, they are merely examples of apparatuses consistent with some aspects of the present disclosure as detailed in the appended claims.

The terms used in the present disclosure are for the purpose of describing particular embodiments only, and are not intended to limit the present disclosure. Unless otherwise defined, technical or scientific terms used in this disclosure should have ordinary meaning as understood by one of ordinary skill in the art to which the disclosure belongs. “First”, “second” and similar words used in the specification and claims of the present disclosure do not represent any order, quantity or importance, but are used only to distinguish different components. Likewise, similar words such as “one”, “a” or “an” do not represent a quantity limit, but represent that there is at least one. “Plurality”. “multiple” or “several” means two or more. Unless otherwise indicated, similar words such as “front”. “rear”. “lower” and/or “upper” are only for convenience of description, and are not limited to one position or one spatial orientation. Similar words such as “including” or “comprising” mean that an element or an item appearing before “including” or “comprising” covers elements or items and their equivalents listed after “including” or “comprising”, without excluding other elements or items. Similar words such as “connect” or “connected with each other” are not limited to physical or mechanical connections, and may include electrical connections, whether direct or indirect. Terms determined by “a/an”. “the” and “said” in their singular forms in the present disclosure and the appended claims are also intended to include plural forms unless clearly indicated otherwise in the context. It should also be understood that the term “and/or” as used herein refers to and includes any or all possible combinations of one or more associated listed items.

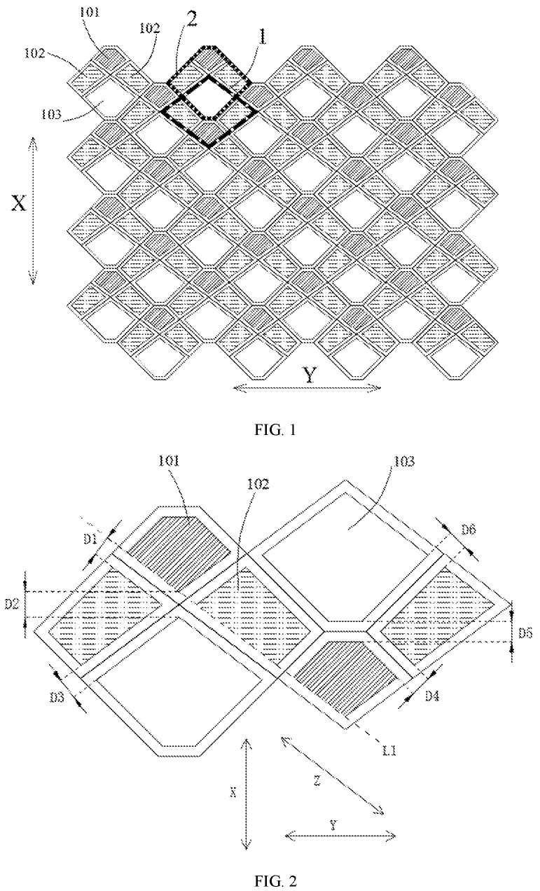

Embodiments of the present disclosure provide a display substrate. As shown in FIG. 1, the display substrate may include a plurality of pixel units arranged in an array. The plurality of pixel units may include a plurality of first pixel units 1 and a plurality of second pixel units 2. In a row direction (a Y direction in FIG. 1), the first pixel units 1 and the second pixel units 2 are alternately arranged: in a column direction (an X direction in FIG. 1), the first pixel units 1 and the second pixel units 2 are alternately arranged. A first pixel unit 1 includes one first sub-pixel 101, two second sub-pixels 102, and one third sub-pixel 103 in a virtual quadrilateral. A second pixel unit 2 includes one first sub-pixel 101, two second sub-pixels 102, and one third sub-pixel 103 in a virtual hexagon. Adjacent first pixel unit 1 and second pixel unit 2 in the column direction share a first sub-pixel 101 or a third sub-pixel 103, and adjacent first pixel unit 1 and second pixel unit 2 in the row direction share a second sub-pixel 102, so that a high-resolution display effect is achieved through a color-borrowing principle.

Each portion of the display substrate according to the embodiments of the present disclosure will be described in detail below.

The display substrate may include a base plate and a driving circuit layer. The base plate may be a rigid base plate. The rigid base plate may be a glass base plate, a PMMA (polymethyl methacrylate) base plate, or the like. The base plate may be a flexible base plate. The flexible base plate may be a PET (polyethylene terephthalate) base plate, a PEN (polyethylene naphthalate two formic acid glycol ester) base plate, or a PI (polyimide) base plate.

The driving circuit layer may be disposed on the base plate. The driving circuit layer may include a plurality of driving transistors. The driving transistors may be film transistors, which is not limited thereto in the embodiments of the present disclosure. The film transistors may be top-gate film transistors, or bottom-gate film transistors. Taking the film transistors being the top-gate film transistors as an example, the driving circuit layer may include an active layer, a gate insulating layer, a gate electrode, an interlayer insulating layer, a source electrode and a drain electrode. The active layer may be disposed on the base plate. The gate insulating layer may be disposed on the base plate, and cover the active layer. The gate electrode may be disposed on a side of the gate insulating layer away from the base plate. The interlayer insulating layer may be disposed on the gate insulating layer, and cover the gate electrode. The source electrode and the drain electrode may be disposed on the interlayer insulating layer, and are connected with the active layer through a via hole passing through the interlayer insulating layer and the gate insulating layer. The display substrate in the embodiments of the present disclosure may further include a planarization layer and a pixel defining layer. The planarization layer may be disposed on a surface of the driving circuit layer away from the base plate, and cover source electrodes and drain electrodes of the driving transistors. The pixel defining layer may be disposed on the planarization layer. The pixel defining layer may be provided with a pixel opening. There are a plurality of pixel openings. The pixel opening is configured to evaporate a light emitting material to form a sub-pixel.

The display substrate may include a plurality of pixel units arranged in an array. The plurality of pixel units include a plurality of first pixel units 1 and a plurality of second pixel units 2. In a row direction (a Y direction in FIG. 1), the first pixel units 1 and the second pixel units 2 are alternately arranged: in a column direction (an X direction in FIG. 1), the first pixel units 1 and the second pixel units 2 are alternately arranged. The plurality of first pixel units 1 may be arranged in an array, and the plurality of first pixel units 1 arranged in an array may include a plurality of first pixel rows and a plurality of first pixel columns. The first pixel row may include a plurality of first pixel units 1 distributed along the row direction. The row direction is an extension direction of the first pixel rows. Any two adjacent first pixel rows may be staggered from each other in the row direction. The plurality of first pixel rows may be distributed along an extension direction of the first pixel columns. The extension direction of the first pixel columns is the column direction. The first pixel column may include a plurality of first pixel units 1 distributed along the column direction. Any two adjacent first pixel columns may be staggered from each other in the column direction. The plurality of first pixel columns may be distributed along the extension direction of the first pixel rows.

The first pixel unit 1 includes one first sub-pixel 101, two second sub-pixels 102, and one third sub-pixel 103 in a virtual quadrilateral. The first sub-pixel 101 and the third sub-pixel 103 in the virtual quadrilateral are respectively disposed at two opposite angles of the virtual quadrilateral, that is, one angle of the first sub-pixel 101 coincides with one of the two opposite angles of the virtual quadrilateral, and one angle of the third sub-pixel 103 coincides with another one of the two opposite angles of the virtual quadrilateral. The two second sub-pixels 102 in the virtual quadrilateral are respectively disposed at another two angles of the virtual quadrilateral, that is, one angle of one second sub-pixel 102 coincides with one of the another two angles of the virtual quadrilateral, and one angle of another second sub-pixel 102 coincides with another one of the another two angles of the virtual quadrilateral.

The two second sub-pixels 102 in the virtual quadrilateral may be symmetrically distributed. A symmetry axis of the symmetrically distributed two second sub-pixels 102 may intersect the first sub-pixel 101 and/or the third sub-pixel 103 in the virtual quadrilateral, and further, a geometric center of the first sub-pixel 101 and/or a geometric center of the third sub-pixel 103 in the virtual quadrilateral (for example, centroid, orthocenter, incenter or circumcenter) may be in the symmetry axis of the two second sub-pixels 102. In addition, the first sub-pixel 101 in the virtual quadrilateral may be presented as an axisymmetric pattern, and the symmetry axis of the symmetrically distributed two second sub-pixels 102 coincides with a symmetry axis of the first sub-pixel 101, that is, in the symmetrically distributed two second sub-pixels 102, a distance between a geometric center of one second sub-pixel 102 and the geometric center of the first sub-pixel 101 is equal to a distance between a geometric center of another second sub-pixel 102 and the geometric center of the first sub-pixel 101. The third sub-pixel 103 in the virtual quadrilateral may be presented as an axisymmetric pattern, and the symmetry axis of the symmetrically distributed two second sub-pixels 102 coincides with a symmetry axis of the third sub-pixel 103, that is, in the symmetrically distributed two second sub-pixels 102, a distance between the geometric center of one second sub-pixel 102 and the geometric center of the third sub-pixel 103 is equal to a distance between the geometric center of another second sub-pixel 102 and the geometric center of the third sub-pixel 103. The symmetry axis of the first sub-pixel 101 may coincide with the symmetry axis of the third sub-pixel 103.

In addition, as shown in FIG. 2, in the virtual quadrilateral, a distance D4 between the second sub-pixel 102 and the first sub-pixel 101 is equal to a distance D6 between the second sub-pixel 102 and the third sub-pixel 103, and the distance D4 between the second sub-pixel 102 and the first sub-pixel 101 is equal to a distance D5 between the first sub-pixel 101 and the third sub-pixel 103.

The plurality of second pixel units 2 may be arranged in an array. The plurality of second pixel units 2 arranged in an array may include a plurality of second pixel rows and a plurality of second pixel columns. An extension direction of the second pixel rows may be the same as the extension direction of the first pixel rows, and an extension direction of the second pixel columns may be the same as the extension direction of the first pixel columns. The second pixel row may include a plurality of second pixel units 2 distributed along the row direction. Any two adjacent second pixel rows may be staggered from each other in the row direction. The plurality of second pixel rows may be distributed along the extension direction of the second pixel columns. The second pixel column may include a plurality of second pixel units 2 distributed along the column direction. Any two adjacent second pixel columns may be staggered from each other in the column direction. The plurality of second pixel columns may be distributed along the extension direction of the second pixel rows.

The second pixel unit 2 includes one first sub-pixel 101, two second sub-pixels 102, and one third sub-pixel 103 in a virtual hexagon. The virtual hexagon may include two first sides/side edges disposed opposite to each other, and the first sides are respectively perpendicular to the column direction. The first sub-pixel 101 and the third sub-pixel 103 in the virtual hexagon are respectively disposed to be attached to the two first sides, that is, one side of the first sub-pixel 101 may coincide with one first side of the virtual hexagon, and one side of the third sub-pixel 103 may coincide with another first side of the virtual hexagon. The two second sub-pixels 102 in the virtual hexagon are respectively disposed at two angles formed by another four sides/edges of the virtual hexagon, that is, one angle of one second sub-pixel 102 coincides with one of the two angles formed by the another four sides of the virtual hexagon, and one angle of another second sub-pixel 102 coincides with another one of the two angles formed by the another four sides of the virtual hexagon. At this time, two sides of the second sub-pixel 102 coincide with the two sides of the virtual hexagon forming the angle respectively.

The two second sub-pixels 102 in the virtual hexagon may be symmetrically distributed. A symmetry axis of the symmetrically distributed two second sub-pixels 102 may intersect the first sub-pixel 101 and/or the third sub-pixel 103 in the virtual hexagon, and further, a geometric center of the first sub-pixel 101 and/or a geometric center of the third sub-pixel 103 in the virtual hexagon may be in the symmetry axis of the two second sub-pixels 102. In addition, the first sub-pixel 101 in the virtual hexagon may be presented as an axisymmetric pattern, and the symmetry axis of the symmetrically distributed two second sub-pixels 102 coincides with a symmetry axis of the first sub-pixel 101, that is, in the symmetrically distributed two second sub-pixels 102, a distance between a geometric center of one second sub-pixel 102 and the geometric center of the first sub-pixel 101 is equal to a distance between a geometric center of another second sub-pixel 102 and the geometric center of the first sub-pixel 101. The third sub-pixel 103 in the virtual hexagon may be presented as an axisymmetric pattern, and the symmetry axis of the symmetrically distributed two second sub-pixels 102 coincides with a symmetry axis of the third sub-pixel 103, that is, in the symmetrically distributed two second sub-pixels 102, a distance between the geometric center of one second sub-pixel 102 and the geometric center of the third sub-pixel 103 is equal to a distance between the geometric center of another second sub-pixel 102 and the geometric center of the third sub-pixel 103. The symmetry axis of the first sub-pixel 101 may coincide with the symmetry axis of the third sub-pixel 103.

In addition, as shown in FIG. 2, in the virtual hexagon, a distance D1 between the second sub-pixel 102 and the first sub-pixel 101 is equal to a distance D3 between the second sub-pixel 102 and the third sub-pixel 103, and the distance D1 between the second sub-pixel 102 and the first sub-pixel 101 is smaller than a distance D2 between the first sub-pixel 101 and the third sub-pixel 103.

The plurality of second pixel columns may correspond to the plurality of first pixel columns one to one. A plurality of second pixel units 2 in one second pixel column and a plurality of first pixel units 1 in a corresponding first pixel column may be alternately arranged in the column direction, and adjacent first pixel unit 1 and second pixel unit 2 may share the first sub-pixel 101 or the third sub-pixel 103. In some embodiments, for the first pixel unit 1, the second pixel unit 2, and the first pixel unit 1 that are sequentially adjacent to each other, the second pixel unit 2 in the middle and the first pixel unit 1 on a side share the first sub-pixel 101, and the second pixel unit 2 in the middle and the first pixel unit 1 on another side share the third sub-pixel 103. The plurality of second pixel rows may correspond to the plurality of first pixel rows one to one. A plurality of second pixel units 2 in one second pixel row and a plurality of first pixel units 1 in a corresponding first pixel row may be alternately arranged in the row direction, and adjacent first pixel unit 1 and second pixel unit 2 may share the second sub-pixel 102.

In the row direction, the first sub-pixel 101 and the third sub-pixel 103 are alternately arranged, and geometric centers of the alternately arranged first sub-pixel 101 and third sub-pixel 103 are on the same straight line: in the column direction, the first sub-pixel 101 and the third sub-pixel 103 are alternately arranged, and geometric centers of the alternately arranged first sub-pixel 101 and third sub-pixel 103 are on the same straight line. For the first sub-pixel 101 and the third sub-pixel 103 alternately arranged in the column direction, the first sub-pixel 101 or the third sub-pixel 103 is shared by adjacent first pixel unit 1 and second pixel unit 2. In addition, as shown in FIG. 2, the first sub-pixel 101 and the second sub-pixel 102 are alternately arranged in a first direction (a Z direction in FIG. 2), and sides of any adjacent first sub-pixel 101 and second sub-pixel 102 in the first direction are aligned, that is, the sides of the first sub-pixel 101 and the second sub-pixel 102 coincide with a straight line L1. The first direction is different from the column direction and the row direction.

A light emitting color of the first sub-pixel 101, a light emitting color of the second sub-pixel 102 and a light emitting color of the third sub-pixel 103 are different from each other. For example, the first sub-pixel 101 is configured to emit red light, the second sub-pixel 102 is configured to emit green light, and the third sub-pixel 103 is configured to emit blue light, which is not particularly limited in the embodiments of the present disclosure. Both the first sub-pixel 101 and the third sub-pixel 103 may be presented as pentagonal, and the second sub-pixel 102 may be presented as quadrilateral, which is not limited thereto in the embodiments of the present disclosure.

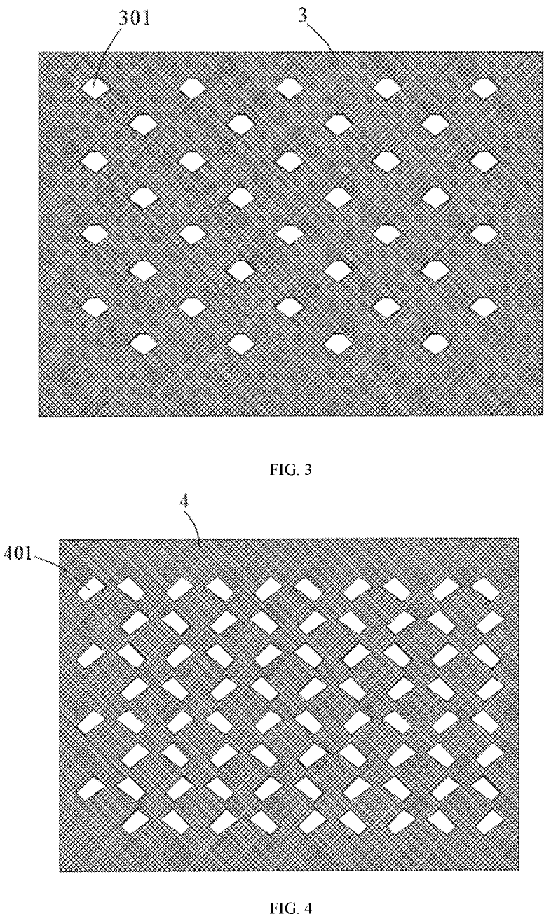

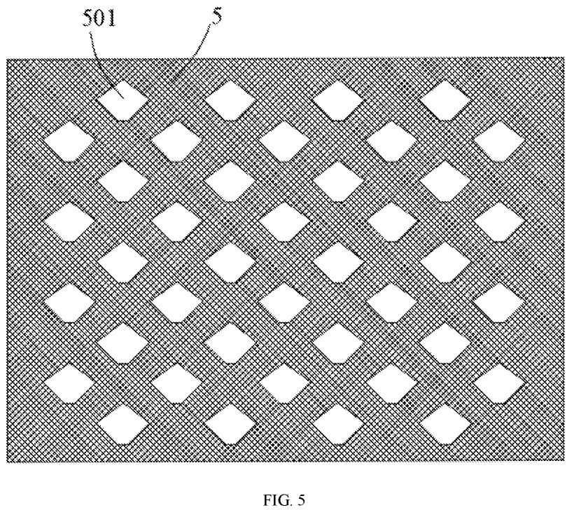

The embodiments of the present disclosure further provide a mask assembly. The mask assembly is used for manufacturing the display substrate according to any one of the above embodiments. The mask assembly may include a first mask plate, a second mask plate, and a third mask plate. As shown in FIG. 3, the first mask plate includes a first substrate 3 and a first opening 301 provided in the first substrate 3. The first opening 301 corresponds to the first sub-pixel 101. As shown in FIG. 4, the second mask plate includes a second substrate 4 and a second opening 401 provided in the second substrate 4. The second opening 401 corresponds to the second sub-pixel 102. As shown in FIG. 5, the third mask plate includes a third substrate 5 and a third opening 501 provided in the third substrate 5. The third opening 501 corresponds to the third sub-pixel 103.

The embodiments of the present disclosure further provide a display panel. The display panel includes the display substrate according to any one of the above embodiments. The display panel further includes a polarizer, etc., and the polarizer is located on a side of the display substrate away from the base plate. The display panel may be used for smart cards, mobile phones, tablet computers, televisions, etc.

The embodiments of the present disclosure further provide a display device. The display device includes the display panel. The display device further includes a housing, and the display panel is embedded in the housing. The display device may be, for example, any device having a display function, such as a mobile phone, a tablet computer, a television, a notebook computer, or a vehicle-mounted device.

The display substrate, the mask assembly and the display panel provided in the embodiments of the present disclosure belong to the same inventive concept, and for description of related details and beneficial effects, reference may be made to each other, which will not be described again.

The above are only preferred embodiments of the present disclosure, which are not intended to make any formal limitation on the disclosure. Although the present disclosure has been disclosed as above in the preferred embodiments, these preferred embodiments are not intended to limit the present disclosure, and any person skilled in the art, without departing from the scope of the technical solutions of the present disclosure, can make some changes or modifications to the technical contents disclosed above as equivalent embodiments with equivalent changes. However, without departing from the contents of the technical solutions of the present disclosure, any simple revisions, equivalent changes and modifications made to the above embodiments based on the technical essence of the present disclosure still fall within the scope of the technical solutions of the present disclosure.

1. A display substrate, comprising:
pixel units arranged in an array and comprising first pixel units and second pixel units, wherein, in a row direction, the first pixel units and the second pixel units are alternately arranged; in a column direction, the first pixel units and the second pixel units are alternately arranged; the first pixel unit comprises a first sub-pixel, two second sub-pixels, and a third sub-pixel in a virtual quadrilateral; the second pixel unit comprises a first sub-pixel, two second sub-pixels, and a third sub-pixel in a virtual hexagon;
wherein adjacent first pixel unit and second pixel unit in the column direction share a first sub-pixel or a third sub-pixel, and adjacent first pixel unit and second pixel unit in the row direction share a second sub-pixel.

2. The display substrate according to claim 1, wherein the virtual hexagon comprises two first sides disposed opposite to each other, and the first sides are respectively perpendicular to the column direction; the first sub-pixel and the third sub-pixel in the virtual hexagon are respectively disposed to be attached to the two first sides, and the two second sub-pixels in the virtual hexagon are respectively disposed at two angles formed by another four sides of the virtual hexagon.

3. The display substrate according to claim 1, wherein the first sub-pixel and the third sub-pixel in the virtual quadrilateral are respectively disposed at two opposite angles of the virtual quadrilateral, and the two second sub-pixels in the virtual quadrilateral are respectively disposed at another two angles of the virtual quadrilateral.

4. The display substrate according to claim 1, wherein the two second sub-pixels in the virtual hexagon are symmetrically distributed; and/or, the two second sub-pixels in the virtual quadrilateral are symmetrically distributed.

5. The display substrate according to claim 4, wherein the first sub-pixel is presented as an axisymmetric pattern, and a symmetry axis of the symmetrically distributed two second sub-pixels coincides with a symmetry axis of the first sub-pixel.

6. The display substrate according to claim 4, wherein the third sub-pixel is presented as an axisymmetric pattern, and the symmetry axis of the symmetrically distributed two second sub-pixels coincides with a symmetry axis of the third sub-pixel.

7. The display substrate according to claim 1, wherein, in the row direction, the first sub-pixel and the third sub-pixel are alternately arranged, and geometric centers of the alternately arranged first sub-pixel and third sub-pixel are on a same straight line; and/or
in the column direction, the first sub-pixel and the third sub-pixel are alternately arranged, and geometric centers of the alternately arranged first sub-pixel and third sub-pixel are on a same straight line.

8. The display substrate according to claim 1, wherein the first sub-pixel and the third sub-pixel are respectively presented as pentagonal, and the second sub-pixel is presented as quadrilateral.

9. The display substrate according to claim 1, wherein, in the virtual hexagon, a distance between the second sub-pixel and the first sub-pixel is equal to a distance between the second sub-pixel and the third sub-pixel, and the distance between the second sub-pixel and the first sub-pixel is smaller than a distance between the first sub-pixel and the third sub-pixel.

10. The display substrate according to claim 1, wherein, in the virtual quadrilateral, a distance between the second sub-pixel and the first sub-pixel is equal to a distance between the second sub-pixel and the third sub-pixel, and the distance between the second sub-pixel and the first sub-pixel is equal to a distance between the first sub-pixel and the third sub-pixel.

11. The display substrate according to claim 1, wherein the first sub-pixel and the second sub-pixel are alternately arranged in a first direction, and sides of any adjacent first sub-pixel and second sub-pixel in the first direction are aligned, wherein the first direction is different from the column direction and the row direction.

12. The display substrate according to claim 1, wherein a light emitting color of the first sub-pixel, a light emitting color of the second sub-pixel, and a light emitting color of the third sub-pixel are different from each other.

13. The display substrate according to claim 12, wherein the first sub-pixel is configured to emit red light, the second sub-pixel is configured to emit green light, and the third sub-pixel is configured to emit blue light.

14. A mask assembly for manufacturing a display substrate according to claim 1, wherein the mask assembly comprises:
a first mask plate comprising a first substrate and a first opening provided in the first substrate, wherein the first opening corresponds to the first sub-pixel;
a second mask plate comprising a second substrate and a second opening provided in the second substrate, wherein the second opening corresponds to the second sub-pixel; and
a third mask plate comprising a third substrate and a third opening provided in the third substrate, wherein the third opening corresponds to the third sub-pixel.

15. A display panel, comprising the display substrate according to claim 1.
